(19) United States
(12) Patent Application Publication
(10) Pub. No.: US 2012/0099269 A1
(43) Pub. Date: Apr. 26, 2012

(54) MOTHERBOARD AND ELECTRONIC DEVICE EMPLOYING THE SAME

(75) Inventors: ZEU-CHIA TAN, Tu-Cheng (TW); ZHI-BIN GUAN, Tu-Cheng (TW)

(73) Assignee: HON HAI PRECISION INDUSTRY CO., LTD., Tu-Cheng (TW)

(21) Appl. No.: 12/980,269

(22) Filed: Dec. 28, 2010

(30) Foreign Application Priority Data
Oct. 25, 2010 (TW) 99136386

(51) Int. Cl. H05K 7/02; H05K 7/20; H05K 7/00

(52) U.S. Cl. 361/679.32; 361/679.02; 361/679.54; 361/679.48; 361/679.49

(57) ABSTRACT

A motherboard for an electronic device includes a main circuit board, an interface, and a sub-circuit. The main circuit board holds a plurality of heat generating element, and the sub-circuit board is electrically connected to the main circuit board through the interface. The sub-circuit board includes a connecting board and a holding board for holding heat generating elements. An end of the connecting board is electrically connected to the main circuit board through the interface, and another end of the connecting board is electrically connected to the holding board. The holding board and the main circuit board are located at opposite ends of the connecting board, and the holding board is spaced with the main circuit board in parallel.

### BACKGROUND

1. Technical Field

The disclosure generally relates to circuit boards, and more particularly relates to, a motherboard used for cooling heat generating elements and an electronic device employing the motherboard.

2. Description of the Related Art

Memory chips, central processing units (CPUs), and other elements in computers, servers or other electronic devices generate a lot of heat in operation. If the heat cannot be effectively transferred in time, temperature of the heat generating elements may increase rapidly, which may reduce the performance and operation life of the elements.

However, since the heat generating elements are located on many different sections of the motherboard, the heat generating elements at downwind location may block the airflow from the heat generating elements at upwind location, resulting in thermal reflux on the heat generating elements and causing temperature difference on different heat generating elements. Thus, the motherboard is not conducive to heat dissipation of the electronic device.

Therefore, there is room for improvement within the art.

### BRIEF DESCRIPTION OF THE DRAWINGS

Many aspects of an exemplary motherboard and electronic device employing the same can be better understood with reference to the following drawings. The components in the drawings are not necessarily drawn to scale, the emphasis instead being placed upon clearly illustrating the principles of the exemplary motherboard and electronic device employing the same. Moreover, in the drawings, like reference numerals designate corresponding parts throughout the several views. Wherever possible, the same reference numbers are used throughout the drawings to refer to the same or like elements of an embodiment.

FIG. 1 is an assembled view of an electronic device having a motherboard, according to an exemplary embodiment.

FIG. 2 is a partially exploded view of the electronic device shown in FIG. 1.

FIG. 3 is similar to FIG. 1, but viewed from the other aspect.

### DETAILED DESCRIPTION

Embodiments of the present disclosure will now be described in detail below, with reference to the accompanying drawings.

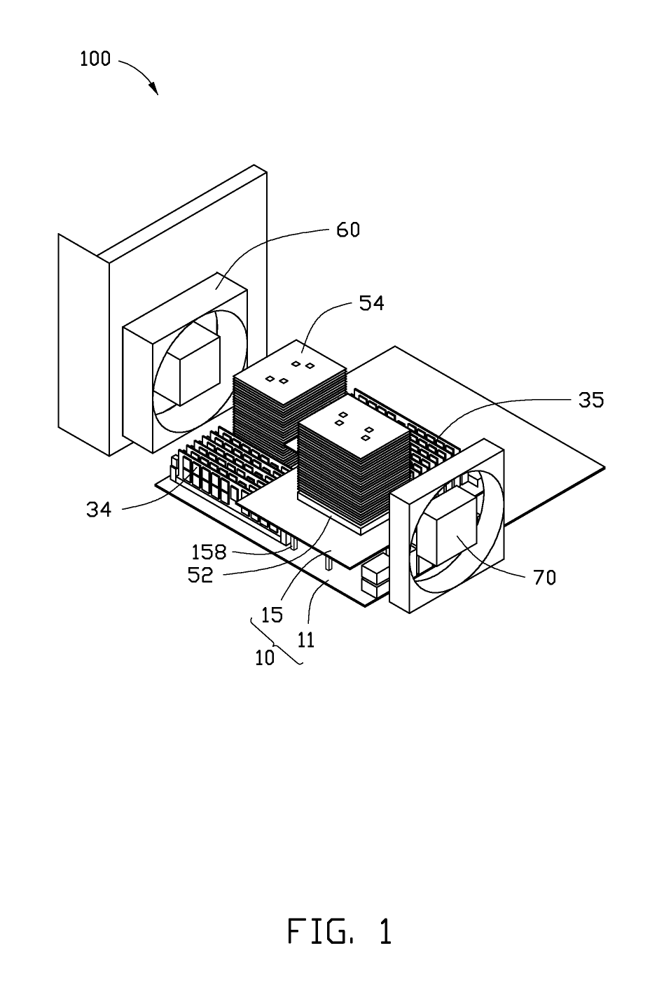

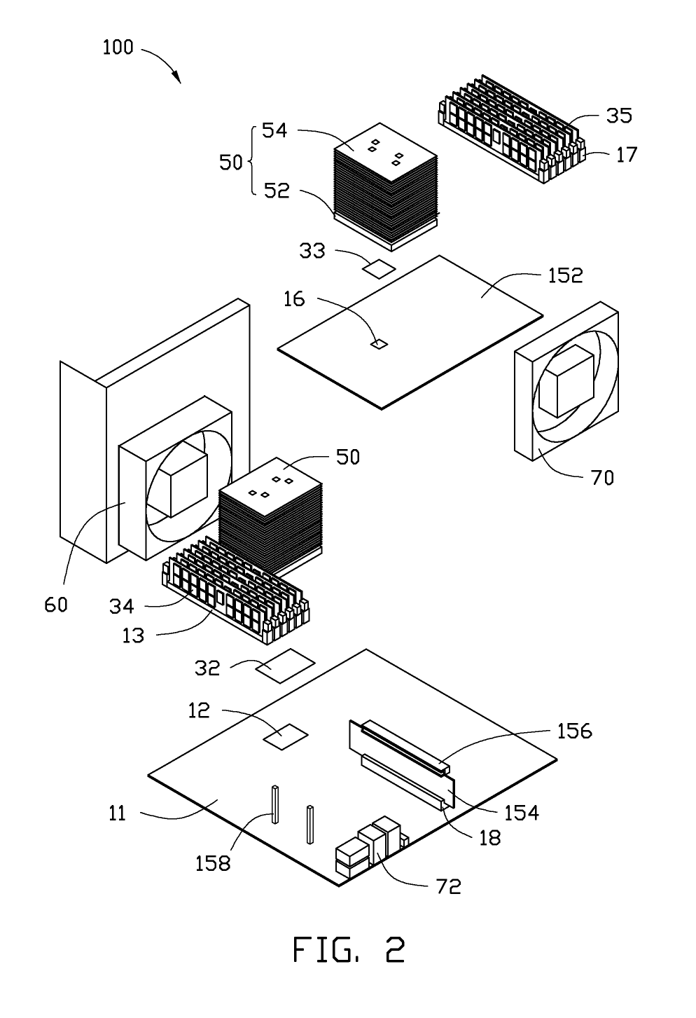

FIGS. 1 and 2 show an exemplary embodiment of an electronic device 100, which can be a computer, sever or other electronic devices. The electronic device 100 includes a motherboard 10, a plurality of heat generating elements (not labeled), two heat sinks 50, a first fan 60, and a second fan 70. The heat generating elements, the heat sinks 50 and the second fan 70 are detachably positioned on the motherboard 10.

The motherboard 10 includes a main circuit board 11, a first processor socket 12, a first memory socket 13, a sub-circuit board 15, a second processor socket 16, a second memory socket 17, and an interface 18 located on the main circuit board 11.

The main circuit board 11 can be a printed circuit board (PCB) and is capable of holding various electronic components (not shown) and electrically connecting these electronic components to each other with conductive traces (not shown) formed in the PCB. The first processor socket 12 and the first memory socket 13 are positioned on the main circuit board 11. In this exemplary embodiment, in order to reduce transmission distance of the signals between the first processor socket 12 and the first memory socket 13, the first memory socket 13 is positioned adjacent to the first processor socket 12. In detail, the first memory socket 13 can be a dual inline memory module (DIMM) socket, electrically connecting to the first processor socket 12 through the conductive traces formed in the main circuit board 11.

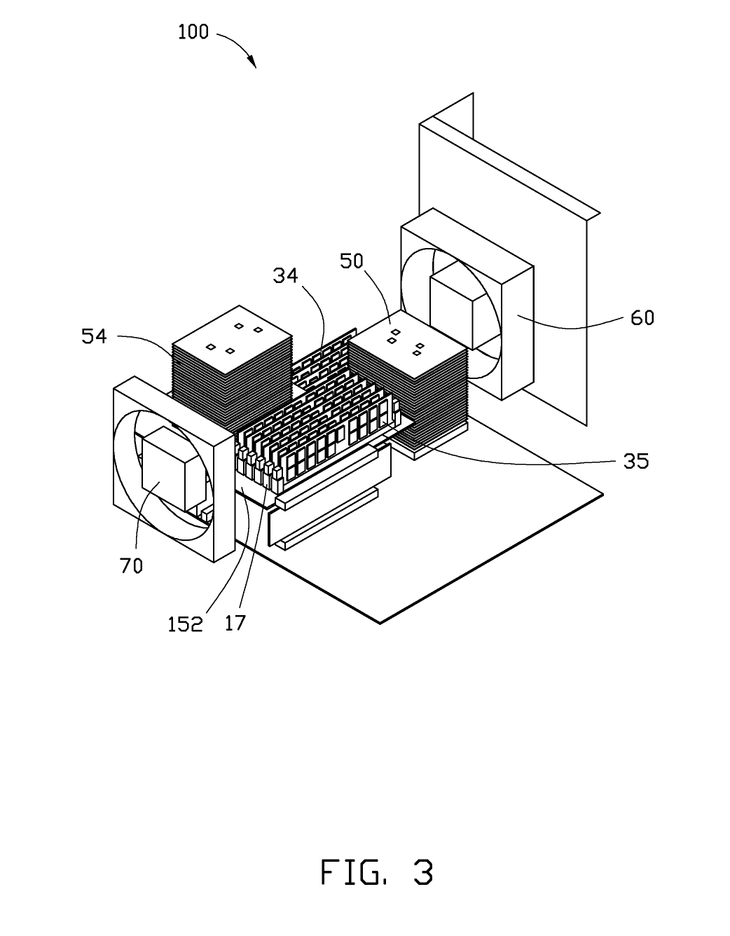

Also referring to FIG. 3, the sub-circuit board 15 is a substantially “L” shaped structure, and includes a holding board 152, a connecting board 154, and a connecting socket 156 electrically connected to the holding board 152 and the connecting board 154. The holding board 152 and the connecting board 154 can be PCBs and support a number of electronic components. The electronic components are electrically connected to each other with the conductive traces formed in the holding board 152 and the connecting board 154.

An end of the connecting board 154 is detachably fixed within the connecting socket 156. The other end of the connecting board 154 is detachably and perpendicularly fixed within the main circuit board 11 through the interface 18, and is electrically connected to the first processor socket 12. In this exemplary embodiment, the thickness of the sub-circuit board 15 is substantially the same as that of the main circuit board 11. The interface 18 can be a quick path interconnect (QPI) interface.

An end of the holding board 152 is detachably received within the connecting socket 156, the holding board 152 is substantially perpendicular to the connecting board 154 and substantially parallel to the main circuit board 11. The second processor socket 16 and the second memory socket 17 positioned on the holding board 152 in parallel, are electrically connected to the main circuit board 11, the first processor socket 12 and the first memory socket 13 through the conductive traces formed in the sub-circuit board 15.

In this exemplary embodiment, in order to reduce transmission distance of the signals between the second processor socket 16 and the second memory socket 17, the second memory socket 17 is positioned adjacent to the second processor socket 16. The second memory socket 17 can be a DIMM socket. In detail, in order to enhance bonding strength between the holding board 152 and the main circuit board 11, at least one supporting post 158 is configured to connect between the holding board 152 and the main circuit board 11. In the exemplary embodiment, there are two supporting posts 158 detachably positioned at the edges of the holding board 152 and the main circuit board 11, preventing the holding board 152 from deformation and damage due to the pressure from the electronic components.

The heat generating elements include a first central processing unit (CPU) 32, a second CPU 33, a first memory 34, and a second memory 35. The first memory 34 and the second memory 35 can be the DIMMs. The first CPU 32, the second CPU 33, the first memory 34 and the second memory 35 are respectively and electrically located at the first processor socket 12, the second processor socket 16, the first memory socket 13 and the second memory socket 17.

Each heat sink 50 can be made with copper, aluminum or other thermal conductive material, and includes a rectangular heat transferring plate 52 and a plurality of fins 54. The fins 54 are positioned on the upper surface of the heat transferring plate 52 and extend upward perpendicular to the upper surface. A plurality of airflow holes (not labeled) are formed between any two adjacent fins 54 to transfer the generated heat. The two heat transferring plates 52 respectively contact the first CPU 32 and the second CPU 33 to transfer the heat generated by the first CPU 32 and the second CPU 33.

The first fan 60 is detachably installed on the housing (not shown) of the electronic device 100 such as a back cover of a computer case, and is adjacent to the first CPU 32 and the first memory 34. The second fan 70 is detachably fixed on the main circuit board 11 through a holder 72, and is adjacent to the second CPU 33 and the second memory 35. Therefore, the first fan 60 and the second fan 70 form a wind guide channel, which can pass through airflow including heat air from the first fan 60 to the second fan 70. The first fan 60 provides adjustable airflows to feed the heat generated by the heat generating elements to the second fan 70, and the second fan 70 then accordingly exhausts the heat out the electronic device 100.

Further referring to FIGS. 1, 2 and 3, in assembly, an end of the connecting board 154 is electrically fixed within the main circuit board 11 through the interface 18; the other end is electrically received within the connecting socket 156. The holding board 152 is electrically fixed to the connecting socket 156 so the holding board 152 is electrically connected to the connecting board 154 and the main circuit board 11. The first CPU 32, the second CPU 33, the first memory 34 and the second memory 35 are electrically and respectively fixed to the first processor socket 12, the second processor socket 16, the memory socket 13 and the second memory socket 17. Since the heat generated by the first CPU 32 and the second CPU 33 is more than the heat generated by the first memory 34 and the second memory 35. The first fan 60 is positioned adjacent to the first CPU 32, the second fan 70 is positioned adjacent to the second CPU 33 to exhaust the maximum amount of heat. In this exemplary embodiment, the distance between the holding board 152 and the main circuit board 11 is greater than the height of the first memory 34 on the main circuit board 11, and the holding board 152 is located at downwind position of the first CPU 32 and the first memory 34. Thus, most heat from the first CPU 32 and the first memory 34 directly passes through the space between the holding board 152 and the main circuit board 11, and is then exhausted out the electronic device 100 by the second fan 70.

Moreover, except for the first processor socket 12, the second processor socket 16, the first memory socket 13 and the second memory socket 17, other sockets for receiving electronic elements can be added or formed on the main circuit board 11 and the sub-circuit board 15 to selectively layout circuits.

In addition, the connecting socket 156 can be omitted, and the sub-circuit board 15 as a whole can be bent toward the direction parallel to the main circuit board 11, forming the connecting board 154 perpendicular to the main circuit board 11 and the holding board 152 parallel to the main circuit board 11.

In summary, in the electronic device 100 of the exemplary embodiment, a number of heat generating elements are regularly positioned on the main circuit board 11 and the sub-circuit board. The connecting board 154 of the “L” shaped sub-circuit board 15 is perpendicularly connected to the main circuit board 11, and the holding board 152 of the sub-circuit board 15 is parallel to the main circuit board 11. Thus, most heat generated by the heat generating elements can pass unhindered through the space between the holding board 152 and the main circuit board 15, avoiding thermal reflux on the heat generating elements. Moreover, the motherboard 10 fully uses the design space of the electronic device 100, enhances cooling capacity of the electronic device 100, and extends the operating life of the heat generating elements.

It is to be understood, however, that even though numerous characteristics and advantages of the exemplary disclosure have been set forth in the foregoing description, together with details of the structure and function of the exemplary disclosure, the disclosure is illustrative only, and changes may be made in detail, especially in matters of shape, size, and arrangement of parts within the principles of exemplary disclosure to the full extent indicated by the broad general meaning of the terms in which the appended claims are expressed.

What is claimed is:

1. A motherboard, comprising:
a main circuit board holding a plurality of heat generating elements;
an interface located at and electrically connected to the main circuit board; and
a sub-circuit board electrically connected to the main circuit board through the interface, the sub-circuit board comprising a connecting board and a holding board for holding the heat generating elements, wherein an end of the connecting board is electrically connected to the main circuit board through the interface, and another end of the connecting board is electrically connected to the holding board, the holding board and the main circuit board are located at opposite ends of the connecting board, and the holding board is spaced with the main circuit board in parallel.

2. The motherboard as claimed in claim 1, wherein the sub-circuit board further comprises a connecting socket, and one end of the connecting board is detachably and electrically connected to the connecting socket, the other end of the holding board is detachably and electrically connected to the connecting socket.

3. The motherboard as claimed in claim 1, wherein the connecting board is electrically and perpendicularly connected to the main circuit board, the holding board is electrically and perpendicularly connected to the connecting board and parallel to the main board.

4. The motherboard as claimed in claim 1, wherein the sub-circuit board further comprises a least one supporting post, and the supporting posts are detachably positioned at the edges of the holding board and the main circuit board to prevent the holding board from deformation and damage.

5. The motherboard as claimed in claim 1, further comprising a first processor socket and a first memory socket, wherein the first processor socket and the first memory socket are positioned on the main circuit board, and the first memory socket is positioned adjacent to the first processor socket to reduce transmission distance of the signals.

6. The motherboard as claimed in claim 5, further comprising a second processor socket and a second memory socket, wherein the second processor socket and the second memory socket are positioned on the holding board, and the second memory socket is positioned adjacent to the second processor socket to reduce transmission distance of the signals between the second processor socket and the second memory socket.

7. The motherboard as claimed in claim 6, wherein the first memory socket and the second memory socket are dual inline memory modules.

8. The motherboard as claimed in claim 1, wherein the interface is a quick path interconnect interface.

9. An electronic device, comprising:
a plurality of heat generating elements that comprise a first CPU, a second CPU, a first memory, and a second memory; and
a motherboard for detachably holding the heat generating elements, comprising:
a main circuit board that supports the first CPU and the first memory;
an interface positioned on and electrically connected to the main circuit board; and
a sub-circuit board electrically connected to the main circuit board, the sub-circuit board comprising a connecting board and a holding board, wherein an end of the connecting board is electrically and detachably connected to the main circuit board through the interface, the other end of the connecting board is electrically and detachably connected to the holding board, the holding board and the main circuit board are located at opposite ends of the connecting board, and the holding board holds the second CPU and the second memory and is parallel to the main circuit board in a interval distance.

10. The electronic device as claimed in claim 9, wherein the sub-circuit board further comprises a connecting socket, and one end of the connecting board is detachably and electrically connected to the connecting socket, the other end of the holding board is detachably and electrically connected to the connecting socket.

11. The electronic device as claimed in claim 9, wherein the connecting board is electrically and perpendicularly connected to the main circuit board, the holding board is electrically and perpendicularly connected to the connecting board and parallel to the main board.

12. The electronic device as claimed in claim 1, wherein the sub-circuit board further comprises a least one supporting post, and the supporting posts are detachably positioned at the edges of the holding board and the main circuit board to prevent the holding board from deformation and damage.

13. The electronic device as claimed in claim 9, further comprising a first processor socket and a first memory socket, wherein the first processor socket and the first memory socket are positioned on the main circuit board, and the first memory socket is positioned adjacent to the first processor socket to reduce transmission distance of the signals.

14. The electronic device as claimed in claim 13, further comprising a second processor socket and a second memory socket, wherein the second processor socket and the second memory socket are positioned on the holding board, and the second memory socket is positioned adjacent to the second processor socket to reduce transmission distance of the signals between the second processor socket and the second memory socket.

15. The electronic device as claimed in claim 14, wherein the first memory socket and the second memory socket are dual inline memory modules.

16. The electronic device as claimed in claim 1, further comprising two heat sinks detachably and respectively positioned on the main circuit board and the holding board, wherein each heat sink comprises a heat transferring plate and a plurality of fins, and the two heat transferring plates respectively contact the first CPU and the second CPU to transfer the heat generated by the first CPU and the second CPU, the fins are positioned on the upper surface of the heat transferring plate and extend upward perpendicular to the upper surface of the transferring plate.

17. The electronic device as claimed in claim 16, wherein any two adjacent fins form a plurality of airflow holes to transfer the heat generated by the heat generating elements.

18. The electronic device as claimed in claim 9, further comprising a first fan and second fan, wherein the first fan is adjacent to the first CPU and the first memory, the second fan is detachably fixed on the main circuit board, and is adjacent to the second CPU and the second memory.

19. The electronic device as claimed in claim 18, wherein the first fan and the second fan form a wind guide channel, the first fan provides adjustable airflows to feed the heat generated by the heat generating elements to the second fan, and the second fan then exhausts the heat out the electronic device accordingly.

20. The electronic device as claimed in claim 9, wherein the interface is a quick path interconnect interface.
